(19) United States
(12) Patent Application Publication
(10) Pub. No.: US 2026/0094644 A1
(43) Pub. Date: Apr. 2, 2026

(54) Superconductor Memory Architecture From Delay Lines

(71) Applicant: The Regents of The University of Michigan, Ann Arbor, MI (US)

(72) Inventors: Jennifer VOLK, Ann Arbor, MI (US); Georgios TZIMPRAGOS, Ann Arbor, MI (US)

(73) Assignee: The Regents of The University of Michigan, Ann Arbor, MI (US)

(21) Appl. No.: 19/347,937

(22) Filed: Oct. 2, 2025

Related U.S. Application Data
(60) Provisional application No. 63/702,285, filed on Oct. 2, 2024.

(51) Int. Cl. G11C 11/44

(52) U.S. Cl. CPC G11C 11/44

(57) ABSTRACT

Recent advances in logic schemes and fabrication processes have renewed interest in using superconductor electronics for energy-efficient computing and quantum control processors. However, scalable superconducting memory still poses a challenge. To address this issue, this disclosure presents an alternative to approaches that solely emphasize storage cell miniaturization by exploiting the minimal attenuation and dispersion properties of superconducting transmission lines to develop a delay-line memory system. The fully superconducting design is operable at frequencies ranging from approximately 20 GHz to 100 GHz and achieves data densities on the order of tens to thousands of megabits per square centimeter. Additionally, the circulating nature of this design allows for minimal control circuitry, eliminates the need for data splitting and merging, and enables inexpensive implementations of sequential access and content-addressable memories.

### GOVERNMENT CLAUSE

This invention was made with government support under FA8702-15-D-0001 awarded by the U.S. Air Force. The government has certain rights in the invention.

### FIELD

The present disclosure relates to superconductor memory architecture from delay lines.

### BACKGROUND

Superconductor electronics (SCEs) feature almost zero static power consumption, speed-of-light energy-efficient interconnects, and clock rates in the 100 s of GHz. In addition to these characteristics, superconductor electronics can serve as facilitators for integrated classical-quantum computers due to their cryogenic nature. Despite advances in fabrication, tools, and logic schemes, however, the lack of a reliable high-speed and high-density superconducting memory continues to impede the development of practical superconductor electronic systems. In this disclosure, a scalable superconducting delay line memory is introduced that takes advantage of the technology's fast switching, zero resistance, and high-kinetic inductance properties.

Previous research has shown that directly applying single flux quantum (SFQ) principles to memory results in designs with low access latency but insufficient density. While arrays of vortex transition (VT) cells have demonstrated the ability to store up to 1 Mbit of data per square centimeter, they face significant limitations for further advancement due to their reliance on superconducting transformers. On the other hand, hybrid architectures that combine SFQ and complementary metal-oxide semiconductor (CMOS) technologies provide better scalability, albeit with long access latencies. CMOS units may scale more effectively than their superconducting counterparts but are slower and usually reside outside of the 4.2 kelvin cryocooler due to their power and thermal footprints. In the search for a viable superconducting memory solution, a considerable effort has also been invested in superconducting memory cells built from novel superconducting-ferromagnetic stack-ups. While promising in many aspects, such designs suffer from complex device structures and thus have their own practical limitations. Lastly, an approach that attempts to find a compromise between the hard-to-scale vortex transition cells and the hard-to-fabricate superconducting-ferromagnetic hybrids is that of superconducting nanowire memory cells. Recent implementation results indicate a bit cell area of 26.5 μm², which is the most compact experimentally verified superconducting storage element to date. However, despite their advantages, superconducting nanowire memory cells are addressed by hTrons, which bring about relatively slow access times, considerably high-power consumption, and high error rates for multi-cell arrays.

This section provides background information related to the present disclosure which is not necessarily prior art.

### SUMMARY

This section provides a general summary of the disclosure, and is not a comprehensive disclosure of its full scope or all of its features.

A memory device is comprised of a memory controller; and a storage element comprised of one or more superconducting transmission lines. Each end of the superconducting transmission line(s) is electrically coupled to the memory controller. The memory controller is configured to receive a pulsed data signal, input the pulsed data signal onto the superconducting transmission line(s), and recirculate the pulsed data signal through the superconducting transmission line(s). The memory controller is also configured to non-destructively read the pulsed data signal from the superconducting transmission line(s) independent from recirculating the pulsed data signal through the superconducting transmission line(s). Additionally, the memory controller is configured to synchronize the pulsed data.

In one embodiment, the superconducting transmission line(s) is (are) configured to transmit single flux quanta with zero resistance.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a high-level diagram of a proposed memory design.

FIG. 2 is a block diagram of an example implementation of the memory controller.

FIGS. 3A and 3B are graphs showing simulation results of the proposed memory device.

FIGS. 4A-4C show the symbol, schematic and simulation results of a destructive readout (DRO) cell.

FIGS. 5A-5C show the symbol, schematic and simulation results of a DRO cell with two readout ports.

FIGS. 6A-6C show the symbol, schematic, and simulation results of a merger cell.

FIGS. 7A-7C are graphs showing bias versus propagation delay for DRO, DRO2R and merger cells, respectively.

FIG. 8 is a chart showing bias margins of the complete memory design for various operating frequencies.

Corresponding reference numerals indicate corresponding parts throughout the several views of the drawings.

### DETAILED DESCRIPTION

Example embodiments will now be described more fully with reference to the accompanying drawings.

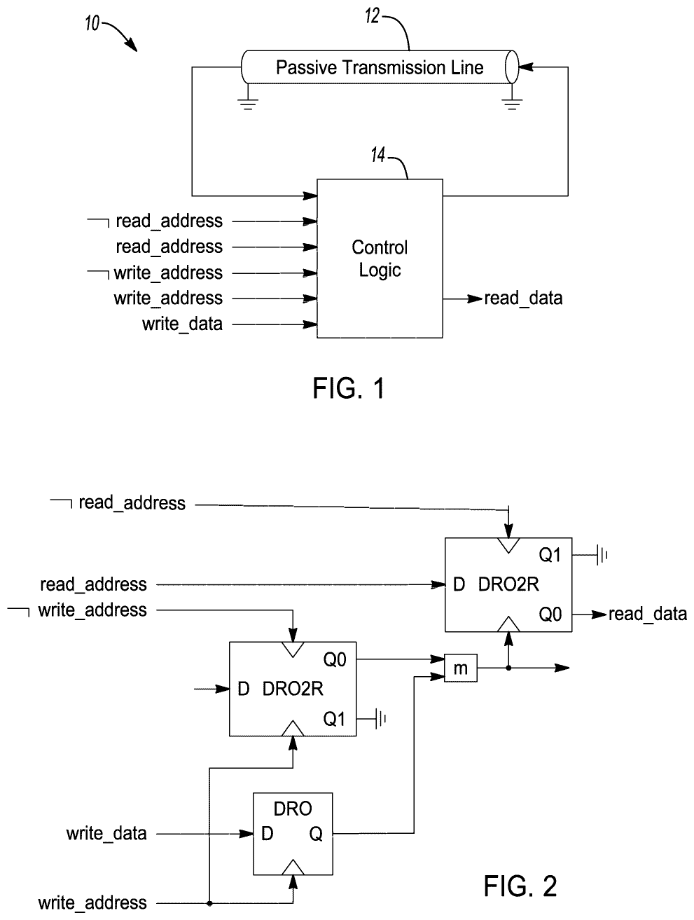

FIG. 1 illustrates a proposed memory device 10. The memory device is comprised of a superconducting transmission line 12 and a memory controller 14. Superconducting transmission lines, including but not limited to passive transmission lines (PTLs), are, in essence, superconducting wires that can transmit single flux quanta with zero resistance, making them ideal for signal routing in large-scale SFQ designs. The superconducting wires may be made of niobium, molybdenum nitride, niobium nitride, or niobium titanium nitride, or other similar materials. If used to form loops, however, they can also be thought of as storage mediums. Each end of the superconducting transmission line 12 is electrically coupled to the memory controller 14 to form a loop. In an example embodiment, the loop is comprised of one or more long Josephson junctions.

During operation, the memory controller 14 is configured to receive a pulsed data signal (e.g., single flux quantum pulses). The memory controller 14 transmits single flux quantum pulses introduced at its input and delivers them after a specific time to its output. The pulses are then picked up and fed back to the loop input, where they are circulated again. Reading from and writing to the memory is achieved in a time-serial manner. This enables the time-sharing of control circuitry, eliminates the need for data splitting and merging, and, in doing so, circumvents the obstacles presented by previous approaches.

The proposed superconducting memory design employs primarily passive components; is fully superconducting; encompasses all typical memory functionalities, such as addressing, data overwrite, and non-destructive readout; and achieves interface speeds of up to 100 GHz in simulation with satisfactory bias margins. The high controller (pulse injection) speed, coupled with the SFQ slowdown caused by high-kinetic inductance materials, boosts memory density by reducing the minimum spacing between subsequent pulses transmitted within superconducting transmission lines. For example, the minimum spacing in niobium nitride nanowires is about 570 times shorter than that of YBCO lines. To validate these hypotheses and quantify the projected gains, this disclosure conducted detailed analog simulations and formulated models that establish the relationship between memory density and various factors such as the operating frequency of the interface circuitry, pulse travel speed in the superconducting transmission lines, and line dimensions.

With continued reference to FIG. 1, memory design consists of a delay line and a control logic block implemented by the memory controller 14. The delay line serves as the circulating loop storage and delays any data that arrives at its input (loop_data_in). The delay introduced by the loop depends on the line's length and the pulse travel speed in the line. At the end of each round trip, the data at the output of the line (loop_data_out) enters the memory controller 14, which serves as a memory interface. The memory controller is responsible for deciding whether signals from the feedback path (loop_data_out) or the input (write_data) will be forwarded to the delay line (loop_data_in) for another round and whether it will be copied and forwarded to the readout port (read_data).

FIG. 2 is a schematic of an example embodiment of the controller 14. In this embodiment, the memory controller 14 is comprised of a DRO cell 23, two DRO2R cells 22, 24, and a merger cell (m) 21 as shown in FIG. 2. Temporally encoded SFQ signals are used for addressing. In an example embodiment, these signals are generated by comparing the value of an address counter with a target address. The merger cell 21 stitches together and forwards all signals that appear on its two input lines to its single output line (loop_data_in). When no pulse arrives on the write_address signal line within the designated interval, a pulse appears on its complementary signal line, ¬write_address. A pulse on the loop_data_out line then flows from a destructive readout cell DRO2R (i.e., a DRO with two outputs) 22 on the left into the delay line input (loop_data_in) on the right, without waiting for other signals. Inversely, when a pulse arrives on the write_address line, a pulse on the loop_data_out line is ignored, the content of the DRO2R 22 is cleared, and write_data is forwarded to the delay line input and readout circuitry. The use of differential signaling for write addressing enables the correction of potential data timing distortions incurred in the control circuitry and the storage loop. The readout circuitry on the right comprises a DRO2R cell 24. For readout to occur, a pulse is loaded through the read_address line. As with the first DRO2R 22, there are two cases of the second DRO2R 24: either a pulse arrives through the loop_data_in line and pushes the stored value to the Q0 output port (read_data), or a pulse on the complementary-read_address line clears the cell, flushing the stored value.

Simulations for the memory device were conducted using WRSPICE, a version of SPICE designed for superconductor electronic designs. The resistively and capacitively shunted JJ model employed in the simulations is based on MIT Lincoln Laboratory's SFQ5ee 100 μA/μm² fabrication process with an IcRn value of 1.65 mV. Bias sources consisted of a current source. In an example embodiment, the current source could be comprised of a resistor tied to a voltage source. To generate SFQ input pulses from an input DC current stimulation, DC-to-SFQ converters were utilized. The subsequent analysis does not consider parasitic inductances associated with shunt resistors, as their impact on circuit performance has been determined to be negligible.

For the design of the memory controller's key components, publicly accessible schematics served as a starting point. To achieve a higher operational frequency and wider bias margins, the number of JJs on the critical path of the corresponding circuit was minimized. To accomplish this, a DRO cell was designed with 4 JJs that matched the critical currents of JJs in the neighboring cells, resulting in improved signal quality. Additionally, the original DRO2R design features output paths that are symmetrical. However, as depicted in FIG. 2, only the Q0 output (data_out0) is connected to the delay line loop. To meet the timing demands of the loop, the internal path from data_in to data_out0 was shortened. The serial inductors in the Merger design were also reduced from their initial values to improve critical path latency. Finally, active splitter cells were eliminated using Ic ranking, achieving fan-out for shared nodes without an overhead of 3 JJs per fan-out of 2. The combined modifications resulted in a memory controller circuit that comprises 29 JJs and a logic path delay of less than10 ps, which is determined by the sum of the DRO2R cell's setup and propagation delays, averaged over its bias margins.

To evaluate performance, the timing resolution was set to 0.5 ps, which was interpolated from the internal step size used by WRSPICE, and delays were measured as peak-to-peak values. Specifically, the DRO and DRO2R propagation delays were measured as the clock-to-Q delay, and the Merger propagation delay was measured as the delay from either input to the output. To determine the upper and lower time bounds of each cell, detailed bias margin analyses were conducted. For bias margin measurements, one can start at the nominal voltage and decremented by steps of 1% of the nominal voltage over the bias range where the circuit operates, to locate the lower limit. Then incremented the nominal voltage to locate the upper limit. Static timing analysis using minimum and maximum intervals was performed to ensure that the timing at the limits of the bias margins meets the hold, setup, and propagation time requirements at different target frequencies.

The memory density of the delay line was calculated using the equation:

$$Density = \frac{f}{w \times v} \qquad ( 1 )$$

where f represents the operating frequency of the memory controller in Hz, w is the superconducting transmission line pitch in m, and v is the travel speed of single flux quanta in m/s.

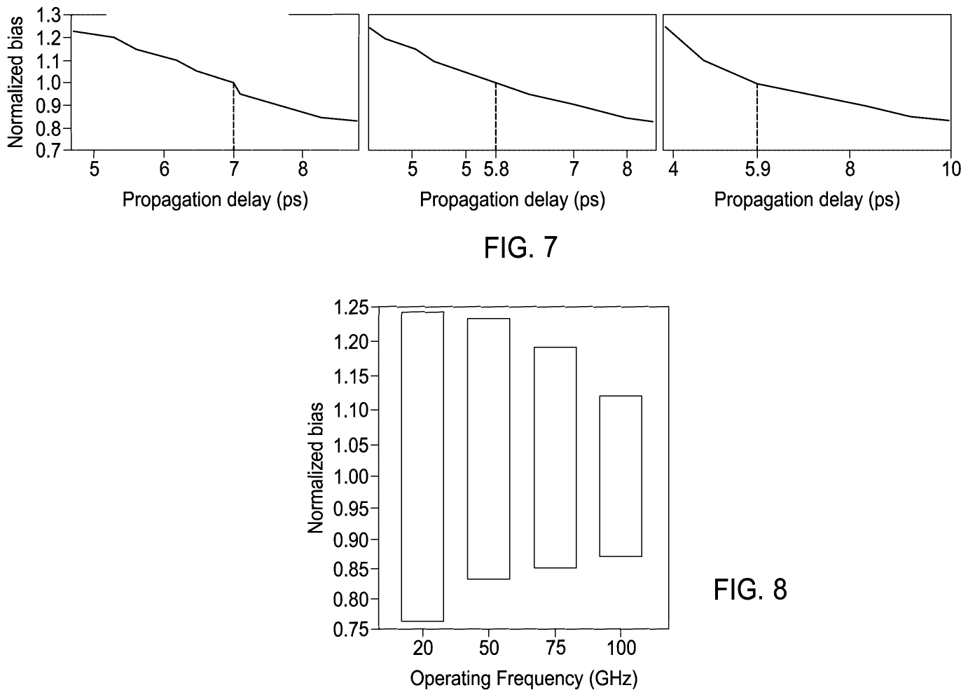

The delay results shown in FIG. 7 indicate a maximum controller operational frequency of 100 GHz. In the conducted memory density analysis, the value of f is selected to span from this value down to 20 GHz to highlight the trade-off between density versus bias margins, as suggested by the findings presented in FIG. 8. Regarding the superconducting transmission line pitch—the sum of the superconducting transmission line width and minimum spacing requirement—this is typically determined by the fabrication process. For example, the well-established SFQ5ee process allows for the reliable fabrication of Nb and MON microstrips and striplines with a 250 nm linewidth and 250 nm spacing, or a pitch of 500 nm. The more advanced SC2 process can reduce the pitch to 240 nm. Further miniaturization down to a pitch of 135 nm and smaller is possible using e-beam lithography.

The velocity factor equation was used to determine the travel speed (v) of single flux quanta in superconducting transmission lines constructed with different materials. The equation is given by:

$$v = \frac{1}{c \sqrt{L \times C}} \qquad ( 2 )$$

Here, c is the speed of light in m/s, L is the inductance per unit length in H/m, and C is the capacitance per unit length in F/m. In cases where geometric inductance is significant, such as in Nb striplines, the inductance scales non-linearly and must be evaluated at each linewidth individually. Based on available experimental measurements, a 250 nm-wide Nb stripline has 0.5 pH/μm, while a 120 nm-wide line has 0.65 pH/μm. For high-kinetic inductors like MON and NbTiN striplines and MON microstrips, the kinetic inductance is directly proportional to the length of the inductor and inversely proportional to its width. This can be calculated by multiplying the known inductance per square values of 8 pH/μm² for MON striplines and microstrips, and 49 pH/μm² for NbTiN striplines, by the unit length divided by the linewidth. Regarding their capacitances, a stripline having a linewidth of 120 nm has a capacitance of 0.19 fF/μm, which is solely determined by the dielectric material and geometry. In an example embodiment, a microstrip having a linewidth of 120 nm has a capacitance of 0.14 fF/μm. In another example embodiment, NbN nanowires have an inductance per square of 82 pH/μm². At a 40 nm linewidth they have an inductance of 2050 pH/μm and a capacitance of 0.044 fF/μm. Inductance and capacitance values for 15 nm NbN nanowires were obtained from modeling results. Effects of coherent quantum phase slips (CQPS) have been observed in NbN films with comparable cross-sectional dimensions. Nevertheless, these effects do not present an issue here, as the kinetic inductance of the films, even with the most extreme linewidths considered, is still one order of magnitude lower than what has been used to observe CQPS. Consequently, the phase-slip amplitude in this case will be e-9 times lower than in systems in which CQPS has been shown to be a significant contributor to conductivity, and for this reason, it is neglected in this analysis.

An approach to further enhance memory density is by vertically stacking multiple layers of superconducting transmission lines. In this case, the memory density increases linearly with the number of superconducting transmission line layers, denoted by N in the equation that follows:

$$Density = \frac{f}{w \times v} \times N \qquad ( 3 )$$

In this regard, a stackup of Nb striplines with nine planarized superconducting layers, stackable stud vias, self-shunted Nb/AIOx-Al/Nb Josephson junctions, and a single layer of MON kinetic inductors has been successfully developed and currently serves as the de facto fabrication process. This stackup, MIT Lincoln Laboratory's state-of-the-art SFQ5ee process, allows for four memory layers based on the typical allocation of ground planes and signal planes. Several advancements to this process are under development, including the addition of self-shunted junctions, which use higher critical current density and can reduce the chip area of digital hardware by 50%, and the introduction of two additional routing layers. Looking forward, foundries have recently announced plans to scale up to sixteen routing layers and one layer for NbTiN kinetic inductors; to the best of our knowledge, however, there is no fundamental limitation that constrains vertical growth.

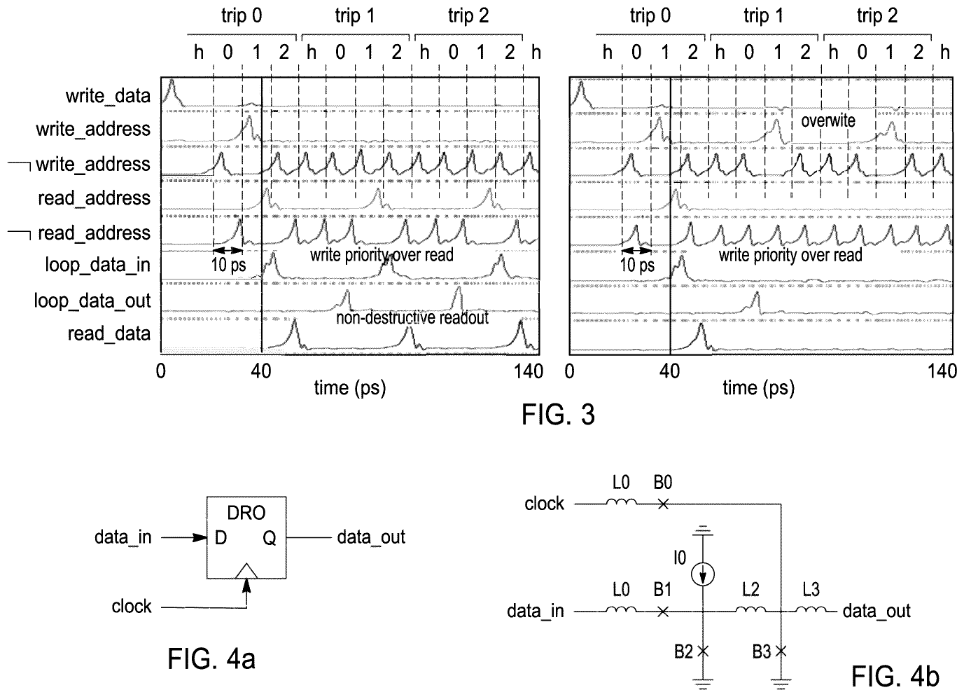

Simulation results for this design are provided in FIGS. 3A and 3B. For illustration purposes, the operating frequency is set to 100 GHz, and the number of supported addresses is set to three. A header interval, h, is needed at the beginning of each memory rotation, or trip, to load data for writing. In FIG. 3A, the loop starts empty and a pulse on the write_data signal line is provided in the header interval of trip 0. During the third interval of the same trip, a pulse is observed on both the write_address and read_address lines, indicating a write operation to and read operation from address 1. After the write_address pulse arrival, a pulse appears on the loop_data_in line, demonstrating a successful memory write operation. After the read_address pulse arrives, a pulse is observed on the read_data line, indicating a successful memory read operation. During the following two trips, the pulse stored in address 1 is successfully retrieved again, which provides evidence of the memory's non-destructive readout capability. In FIG. 3B, the first rotation, trip 0, is identical to that of 3A. However, in trip 1, the pulse stored in address 1 is successfully overwritten, as indicated by the absence of pulses in the loop_data_in and loop_data_out lines after the overwrite.

Note that the presented memory system allows one to search and operate on all of the memory contents while waiting for the entire circulation time to pass, thereby eliminating the need to broadcast to or continuously poll individual cells. The design's rotating nature not only circumvents classic fan-in and fan-out limitations of superconductor electronics but also supports the addition of multiple write and read ports and the inexpensive implementation of content-addressable memories.

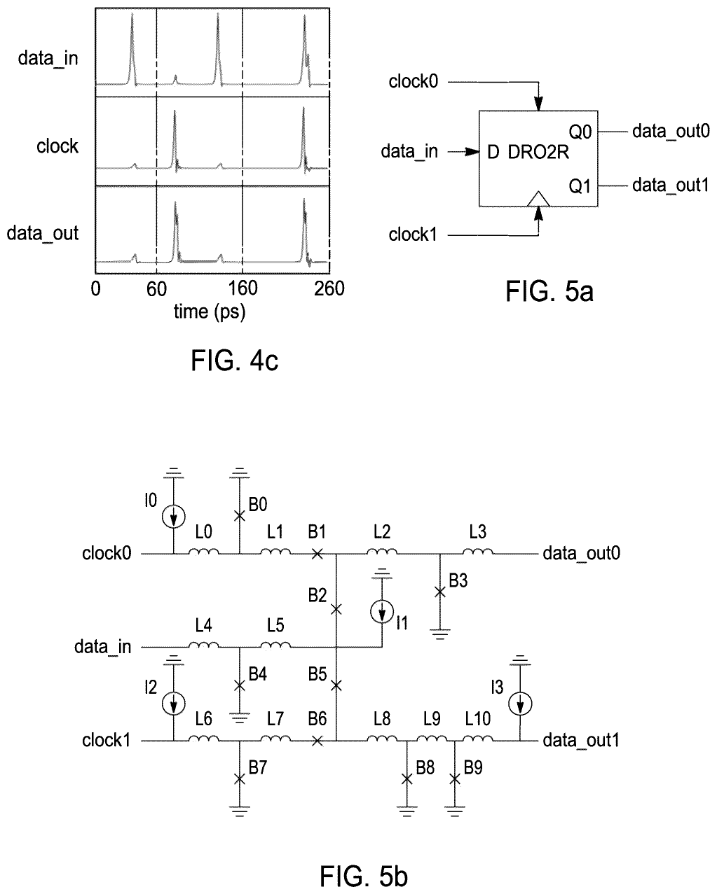

FIGS. 4A-4C show the symbol, schematic and simulation results for a destructive readout cell. In FIG. 4B, an incoming data_in SFQ pulse is stored in the superconducting quantum interference device (SQUID) formed by B2-L2-B3 until a clock pulse arrives. The arrival of a clock pulse switches B3 and releases an SFQ pulse on data_out. In one example, the corresponding circuit parameters are: L0=0.7 pH; L1=1.3 pH; L2=5 pH; L3=1.6 pH; B0, B3=227 μA; B1, B2=188 μA; and I0=125 μA. Shunt resistors for B0 and B3 are 3.3Ω and for B1 and B2 are 3.4Ω.

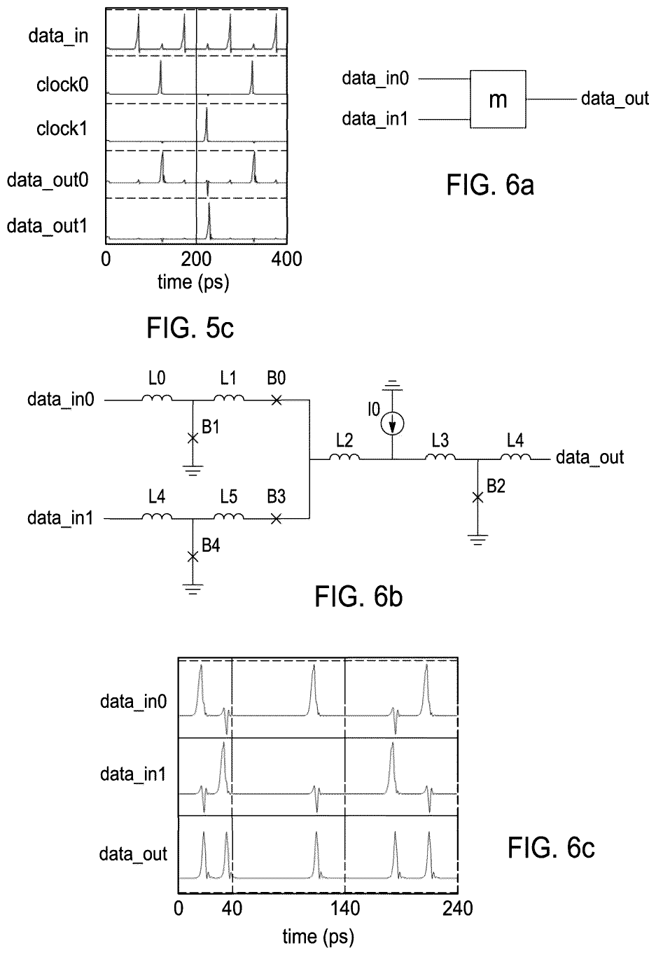

FIGS. 5A-5C show the symbol, schematic and simulation results of a DRO cell with two readout ports. The DRO2R cell performs largely the same operation as the DRO. In the case of the DRO2R cell, the storage element is shared between two parallel loops: B4-L5-B2-L2-B3 and B4-L5-B5-L8-B846 as seen in FIG. 5B. A pulse appearing on either clock input will clear the stored SFQ and push it to the respective output line. In one example, the corresponding circuit parameters are: L0, L6=0.3 pH; L1, L3=2 pH; L2, L8=0.12 pH; L4=0.5 pH; L5=5 pH; L7=3 pH; L9=5.5 pH; L10=0.52 pH; B0, B7=325 μA; B1, B6, B8=162 μA; B2, B5=197 μA; B3=152 μA; B4=237 μA; B9=223 μA; and 10, I1, I2, I3=176 μA. Shunt resistors for B0 and B7 are 2Ω; for B1, B3, B6, and B8, 4.2Ω; for B2 and B5, 3.4Ω; for B4, 2.8Ω; and for B9, 3Ω.

FIGS. 6A-6C show the symbol, schematic, and simulation results of a merger cell. As its name implies, this design passes incoming SFQ pulses from either of its two input ports to its output. To prevent backward propagation of an input SFQ from the opposite line, two blocking Josephson junctions, B0 and B3, are used as seen in FIG. 6B. In one example, the corresponding circuit parameters are: L0=1 pH; L1=0.46 pH; L2=0.2 pH; L3=1.3 pH; L4=0.8 pH; B0, B3=197 μA; B1, B2, B4=220 μA; and 10=500 μA. Shunt resistors for B1, B2, and B4 are all 3Ω.

As is the case for any system, the electrical and timing properties of these cells affect both the performance and functionality of the proposed memory. In particular, electrical issues, typically brought on by susceptibility to parametric variation, can lead to fatally under- or over-biased Josephson Junctions (JJs), which in turn can lead to circuit dysfunction, or delayed or early switching times. To avoid erroneous behavior and ensure correct system timing, the effects of under-biasing and over-biasing are first examined at the cell level. Performing this bias analysis for cells in isolation, however, is not sufficient because it excludes the loading effects that are present in a system setting. To account for loading, iterative measurements and component tuning are carried out in an in-situ approach to achieve the desired timing. Accordingly, each cell is fully loaded by the remaining components in the memory controller. The results of this process are shown in FIGS. 7A-7C. Nominal cell delays are indicated in red. DRO and DRO2R delays are measured as clock-to-Q delays, while the Merger delay is measured as the propagation delay from either of the inputs to the output. Delays in each cell increase as bias decreases, and decrease as bias increases. To make bias margins symmetric, a set of component parameters is chosen that centers the nominal delay of each cell between the upper and lower time bounds of the controller.

Using interval analysis and the above delays, the maximum operating frequency of the controller is estimated, and the cell tuning and bias margin measurements are repeated. Another round of bias margin measurements is conducted, wherein the bias of the entire design is varied instead of individual cells. FIG. 8 illustrates results for frequencies ranging from 20 to 100 GHz. Note that electrical issues-caused by, for example, Josephson junctions that are subject to the above biasing concerns and that switch too frequently or not at all-drive limitations in bias margin width at lower frequencies, while timing issues are the limiter at higher frequencies. This happens because timing constraints get tighter as the address timing interval is reduced. For example, at 100 GHz, the address timing interval is just 10 ps, which leaves little room for the same variations in propagation delay that one observed in FIGS. 7A-7C. SPICE simulations show bias margins ranging from ±24% (at 20 GHz) to ±13% (at 100 GHz), which surpass the widely accepted ±10% threshold.

The physical storage density—that is, bits per area—of the proposed memory device 10 depends on (1) the PTL's linewidth and spacing requirements, set by the fabrication process; (2) the travel speed of SFQ pulses in the PTL, set by the material of choice and the line topology; (3) the relative timing between two adjacent SFQ pulses, set by the controller's operating frequency; and (4) the number of PTL memory routing layers.

In an example embodiment, a Nb stripline of 250 nm linewidth with a minimum spacing of 250 nm propagates SFQ pulses at a speed of 0.3c. This leads to data densities of up to 0.9 Mbit/cm² at 100 GHz, if four metal routing layers are used. Reducing the Nb stripline linewidth and minimum spacing from 250 to 120 nm in another embodiment results in densities of up to 1.9 Mbit/cm². In a third embodiment, switching device material and topology to an MON kinetic inductor microstrip with the same dimensions, available on just one layer within MIT Lincoln Laboratory's SFQ5ee and SC2 processes, causes the travel speed of pulses in the line to fall by about 6×. This slowdown yields densities of up to 1.4 and 4.0 Mbit/cm² for 250 nm and 120 nm linewidths, respectively, at 100 GHz. By default, the SFQ5ee and SC2 fabrication processes allow for one MON high-kinetic inductance layer, four Nb signal-routing layers, and three ground planes, based on the typical allocation. An increase in the number of the MoN high-kinetic inductance layers in a fourth embodiment, from one to four, transforms the line topology into that of a stripline and increases the data density to 3.2 Mbit/cm² at 20 GHz and 19 Mbit/cm² at 100 GHz for a 120 nm linewidth and 120 nm spacing.

It is evident that the use of materials with increasingly high kinetic inductance is conducive to higher densities. To this end, this disclosure explores the potential of NbTiN striplines that exhibit approximately an order of magnitude higher inductance than their MON counterparts and propagate SFQ pulses at a speed of 0.011 c. Results indicate that for a NbTiN stripline with 100 nm width, 120 nm spacing, four metal routing layers, and controller frequencies between 20 and 100 GHz, the estimated data densities range from 10.7 to 53.3 Mbit/cm².

A more forward-looking approach comes from the use of NbN kinetic inductor nanowires. In the case of an experimentally-tested NbN nanowire with 40 nm linewidth, the inductance scales to 2050 pH/μm. A roughly proportional drop in capacitance keeps the pulse travel speed the same, 0.011 c, but the reduced linewidth pushes the maximum data density to 75.4 Mbit/cm² at 100 GHz. A reduction in linewidth to 15 nm causes the inductance to increase to 5467 pH/μm, which drops the travel speed to 0.007 c and increases data density to 140.3 Mbit/cm² at 100 GHz. This is equivalent to a physical pulse spacing of 21 μm, about 600× shorter than that in the YBCO line. Moreover, assuming that CMOS layer stacking techniques—such as those used to create 100-layer stacks in V-NANDs—could be applied to superconductor technology, this NbN nanowire technology could provide a memory density of 3507 Mbit/cm² at 100 GHz operating speed.

The microarchitectural features of the most prominent computer systems have historically co-evolved with the technology and devices that embody them. For instance, in the case of CMOS, the combination of cheap transistors and power-hungry interconnects has motivated the development of designs that trade off resource redundancy for reduced data movement. By contrast, data movement in superconductor electronics is cheaper than switching due to the nearly lossless nature of superconducting interconnects. Therefore, the critical question-which this disclosure addresses—is whether, in the case of superconductor electronics, one can capitalize on the unique properties of superconducting interconnects to improve hardware efficiency, simplicity, and density.

Previous attempts to develop cryogenic memory technology, which functions at temperatures of 4 kelvin or below, have predominantly centered on creating individual storage cells that can subsequently be arranged in a standard grid configuration. While such configurations have been effective in CMOS, they cannot fully leverage the advantage that superconductor electronics provide in terms of low-cost signal transmission. Additionally, they often disregard the forthcoming obstacles that arise from the limitations of inductor scaling and fan-in/out, as well as the significant power consumption and long access times, high device complexity, and increased bit-error rate that come with the suggested structures.

The presented approach departs from this tradition and exploits superconducting passive transmission lines for the construction of a delay-line memory system. From a device perspective, delay lines are easy to construct and offer high signal fidelity. For instance, experimental results indicate that SFQ pulses can travel over 7 mm-long superconducting transmission lines without re-amplification. Moreover, the footprint and kinetic inductance of superconducting transmission lines can be substantially modified by their topology, material composition, and fabrication process. By harnessing these characteristics in conjunction with our high-speed SFQ control logic circuitry, we anticipate achieving data density improvements of two orders of magnitude compared to the current state of the art. This can be accomplished while retaining the same number of metal (memory) layers as existing fabrication processes. The method of vertical growth-common in technologies like CMOS V-NANDs—is also anticipated to increase data density gains by an additional order of magnitude.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A memory device, comprising:
a memory controller; and
a superconducting transmission line having each end electrically coupled to the memory controller and serving as a storage element;
wherein the memory controller is configured to receive a pulsed data signal, input the pulsed data signal onto the superconducting transmission line, and recirculate the pulsed data signal through the superconducting transmission line(s).

2. The memory device of claim 1 wherein the superconducting transmission line is configured to transmit single flux quanta with zero resistance.

3. The memory device of claim 1 wherein the superconducting transmission line is comprised of niobium.

4. The memory device of claim 1 wherein the superconducting transmission line is comprised of molybdenum nitride, niobium nitride, or niobium titanium nitride.

5. The memory device of claim 1 wherein the memory controller is configured to non-destructively read the pulsed data signal from the superconducting transmission line independent from recirculating the pulsed data signal through the superconducting transmission line.

6. The memory device of claim 1 wherein the memory controller is configured to synchronize the pulsed data signal in the superconducting transmission line using differential signaling.

7. The memory device of claim 1 wherein memory controller is configured to replace the pulsed data signal in the superconducting transmission line with another pulsed data signal or no signal.

8. A memory device, comprising:
a memory controller; and
a loop having each end electrically coupled to the memory controller and serving as a storage element, wherein the loop is comprised of one or more long Josephson junctions forming a transmission line;
wherein the memory controller is configured to receive a pulsed data signal, input the pulsed data signal onto the loop, and recirculate the pulsed data signal through the loop.

9. The memory device of claim 8 wherein the memory controller is configured to non-destructively read the pulsed data signal from the loop independent from recirculating the pulsed data signal through the loop.

10. The memory device of claim 8 wherein the memory controller is configured to synchronize the pulsed data signal in the loop using differential signaling.

11. The memory device of claim 8 wherein memory controller is configured to replace the pulsed data signal in the loop with another pulsed data signal or no signal.

12. The memory device of claim 8 wherein the one or more long Josephson junctions are at least partly comprised of niobium.

13. The memory device of claim 8 wherein the one or more long Josephson junctions are comprised of superconducting materials, including but not limited to molybdenum nitride, niobium nitride, and niobium titanium nitride.
